(19) United States
(12) Patent Application Publication
(10) Pub. No.: US 2013/0295732 A1
(43) Pub. Date: Nov. 7, 2013

(54) METHOD FOR MAKING FIELD EFFECT TRANSISTOR

(71) Applicants: Dongping Wu, Shanghai (CN); Yinghua Piao, Shanghai (CN); Zhiwei Zhu, Shanghai (CN); Shili Zhang, Stockholm (SE); Wei Zhang, Shanghai (CN)

(72) Inventors: Dongping Wu, Shanghai (CN); Yinghua Piao, Shanghai (CN); Zhiwei Zhu, Shanghai (CN); Shili Zhang, Stockholm (SE); Wei Zhang, Shanghai (CN)

(73) Assignee: FUDAN UNIVERSITY, Shanghai (CN)

(21) Appl. No.: 13/390,328

(22) PCT Filed: Sep. 28, 2011
(86) PCT No.: PCT/CN11/80254

§ 371 Date: Feb. 13, 2012

(30) Foreign Application Priority Data
Jan. 17, 2011 (CN) 201110009523.9

(51) Int. Cl. H01L 29/66

(52) U.S. Cl. CPC H01L 29/66477
USPC 438/163; 438/290

(57) ABSTRACT

The present invention provides a method for making a field effect transistor, comprising of the following steps: providing a silicon substrate with a first type, forming a shallow trench by photolithography and etching processes, and forming silicon dioxide shallow trench isolations inside the shallow trench; forming by deposition a high-K gate dielectric layer and a metal gate electrode layer on the substrate and the shallow trench isolations; forming a gate structure by photolithography and etching processes; forming source/drain extension regions by ion implantation of dopants of a second type; depositing an insulating layer to form sidewalls tightly adhered to the sides of the gate; forming source/drain regions and PN junction interfaces between the source/drain region and the silicon substrate by ion implantation of dopants of the second type; and performing microwave annealing to activate implanted ions. The novel process of making a field effect transistor in the present invention can achieve impurity activation in the source/drain area at a low temperature and can reduce the influence of source/drain annealing on high-K gate dielectric and metal gate electrode.

### TECHNICAL FIELD

The present invention relates to a method for semiconductor manufacturing, especially to a method for making field effect transistor.

### BACKGROUND

With the development of semiconductor technology, Metal-Oxide-Semiconductor Field Effect Transistor (MOSFET) has been widely used. Over recent years, microelectronics technology about silicon integrated circuits has been rapidly developed, and the development of integrated circuit chips conforms basically to Moore's Law, meaning the density of integration on semiconductor chips doubles every 18 months.

However, the channel length of MOSFET decreases continuously as the density of integration of semiconductor chips continually increases. Severe short channel effect can result when the channel length of MOSFET becomes very short. For example, after the channel length is shortened to a certain extent, the proportion of depletion regions of source/drain junctions in the entire channel increases and the quantity of electric charges required by the formation of an inversion layer at the silicon surface under the gate is reduced, so the threshold voltage of the transistor is reduced. At the same time, the charges along the width of the channel in the depletion regions in the substrate cause the threshold voltage to increase. When the channel with decreases to be in the same order of magnitude of the depletion region width, the increase in the threshold voltage is even more prominent, leading to performance deterioration or even abnormal operation of the integrated circuit chip.

Better control for short channel effect can be reached by enhancing the control of the gate on the channel and by adopting shallower source/drain structure. Over the past few decades, source/drain depth of MOSFET devices, thickness of gate oxide layer and length of gate have been substantially reduced proportionally so as to control the performance of short channel devices. Typically, reducing the effective thickness of gate oxide layer is the most direct way of enhancing the control of the gate on channel.

So far, more than ten years of research have been conducted on the use of high dielectric constant (high-K) dielectrics as gate insulating layer. The dielectric with high dielectric constant, e.g. hafnium-based oxide, can result in effective gate oxide thickness below 1 nanometer, while maintaining gate tunneling current at a relatively low level. In addition to using high-K dielectric as gate insulating layer to replace traditional silicon dioxide, the use of metal gate electrode to replace traditional polycrystalline silicon gate electrode can eliminate depletion effect of polycrystalline silicon and hence further reduce the effective thickness of gate insulating layer, so that the control of gate electrode on the channel is further improved.

In order to obtain shallower PN junctions between source/drain regions and the substrate, research has been focused on ultra-low-energy ion implantation and millisecond level thermal annealing process, such as laser annealing and flash annealing. In order to sufficiently activate the implanted impurity ions, the highest temperature reached by conventional rapid thermal annealing is at least 900, sometimes even over 1000° C. At present, high-K gate dielectric/metal gate electrode and millisecond level laser annealing process are adopted simultaneously in the state-of-the-art field effect transistor technology in industry. Conventional process technology of MOSFET devices adopts Gate-First process, i.e. gate insulating layer/gate electrode is formed prior to thermal activation of implanted dopants in source/drain region. Nonetheless, the influence of high-temperature thermal annealing process on high-K gate dielectric and silicon substrate as well as on interface of high-K gate dielectric and metal gate electrode will lead to increase of the effective thickness of gate dielectric and to drifting and unstable threshold voltage. Consequently, the mainstream high-K gate dielectric/metal gate electrode technologies used in mass production generally adopt complex Damascene Gate-Last process. This process is characterized by formation of high-K gate dielectric/metal gate electrode after the impurity activation in source/drain region, thereby eliminating the influence derived from high-temperature annealing, but it is more complex and has higher cost compared with the Gate-First process. Furthermore, the miniaturization capability of the Damascene Gate-Last process is poorer owing to the limitation of etching and filling of high aspect openings.

Eliminating or reducing the influence of dopant activation thermal annealing in source/drain regions on high-K gate dielectric and metal gate electrode is crucial to the development of MOSFET process integration and device structures in the future.

In view of the aforementioned challenges, the present invention provides an improved method for preparing field effect transistor to eliminate or improve the above problems.

### SUMMARY

The present invention solves the technological problem related to providing a process for making field effect transistors, which alleviates or eliminates the effect of annealing for dopant activation at source/drain regions on the interface between high-K gate dielectric and silicon substrate and the interface between the high-K gate dielectric and metal gate electrode.

The present invention solves the above technological problems according to the following technological scheme.

Embodiments of the present invention provides a method of making a field-effect transistor, the method comprising:
providing a silicon substrate of a first type, forming shallow trenches using photolithography and etching processes, and forming shallow trench isolation structures by growing silicon dioxide in the shallow trenches;
forming by deposition a high-K dielectric layer and a metal gate electrode layer over the substrate and the shallow trench isolation structures;
forming a gate structure using photolithography and etching processes;
implanting dopant ions of a second type to form source/drain extension regions;
depositing an insulating layer, and forming sidewalls on sides of the gate electrode;
implanting dopant ions of the second type to form source/drain regions of the field-effect transistor of the second type and to form P-N junctions at the interface between the source/drain regions and the silicon substrate; and
annealing using microwave to activate the implanted ions.

The substrate of the first type can be silicon or silicon-on-insultor.

The high-K dielectric layer can be hafnium oxide, hafnium silicon oxide, hafnium silicon oxynitride, silicon oxynitride, aluminum oxide, lanthanum oxide, zirconium oxide, a multilayer structure formed by a combination of two of more thereof, or a mixed layer of two or more thereof.

The metal gate electrode layer can be titanium nitride, tantalum nitride, metal silicide, tungsten, aluminum, ruthenium, platinum, a multilayer structure formed by a combination of two of more thereof, a mixed layer of two or more thereof, or a multilayer structure formed by a combination of polysilicon and one or more thereof.

The metal silicide can be a compound formed of silicon and any of nickel, titanium, cobalt.

The substrate of the first type can be a P-type substrate, the dopants of the second type can be N-type dopants, and implanting ions can be implanting phosphorus or arsenic ions. Alternatively, The substrate of the first type can be a N-type substrate, the dopants of the second type can be P-type dopants, and implanting ions can be implanting boron, boron fluoride, or indium ions.

Dopant ions of the first type can be implanted to form halo regions before forming the source/drain extension regions in order to improve the short channel effect of the device.

Alternatively, dopant ions of the first type are implanted to form halo regions after forming the source/drain extension regions in order to improve the short channel effect of the device.

The substrate of the first type can be a P-type substrate, and the dopants of the first type can be boron, boron fluoride, or indium. Alternatively, the substrate of the first type can be a N-type substrate, and the dopants of the first type can be phosphorus or arsenic.

In certain embodiments, annealing temperature does not exceed 400° C.

Compared to conventional technologies, the present invention provides the advantages that, according to the novel method of making field-effect transistors, the high-K dielectric and/or metal gate electrode are formed before activation of the dopants in the source/drain regions, and the dopants are activated using microwave annealing techniques, allowing the dopants in the source/drain regions to be activated under relatively low temperature, thereby lessening the effect of source/drain annealing on the high-K dielectric and/or metal gate electrode.

### BRIEF DESCRIPTION OF THE DRAWINGS

FIG. 1 illustrates forming shallow trench isolation structures on a semiconductor substrate in a process of making field-effect-transistor.

FIG. 2 illustrates forming a gate stack structure in the process of making field-effect-transistor.

FIG. 3 illustrates using photolithography, etching to form the gate stack structure in the process of making field-effect-transistor.

FIG. 4 illustrates implanting ions to form source/drain extension regions in the process of making field-effect-transistor.

FIG. 5 illustrates depositing a insulating layer and forming sidewalls in the process of making field-effect-transistor.

FIG. 6 illustrates implanting ions and annealing using microwave to activate the ions in the process of making field-effect-transistor.

### DETAILED DESCRIPTION OF THE EMBODIMENTS

Embodiments of the present invention are described in more detail below with reference to the drawings.

The method for making field-effect transistors according to embodiments of the present invention can be used to make both N-type and P-Type transistors, their differences being in the dopant types of the substrate and the source/drain regions, that is, N-type transistors have their substrate doped with P-type dopants, and P-type transistors have their substrate doped with N-type dopants.

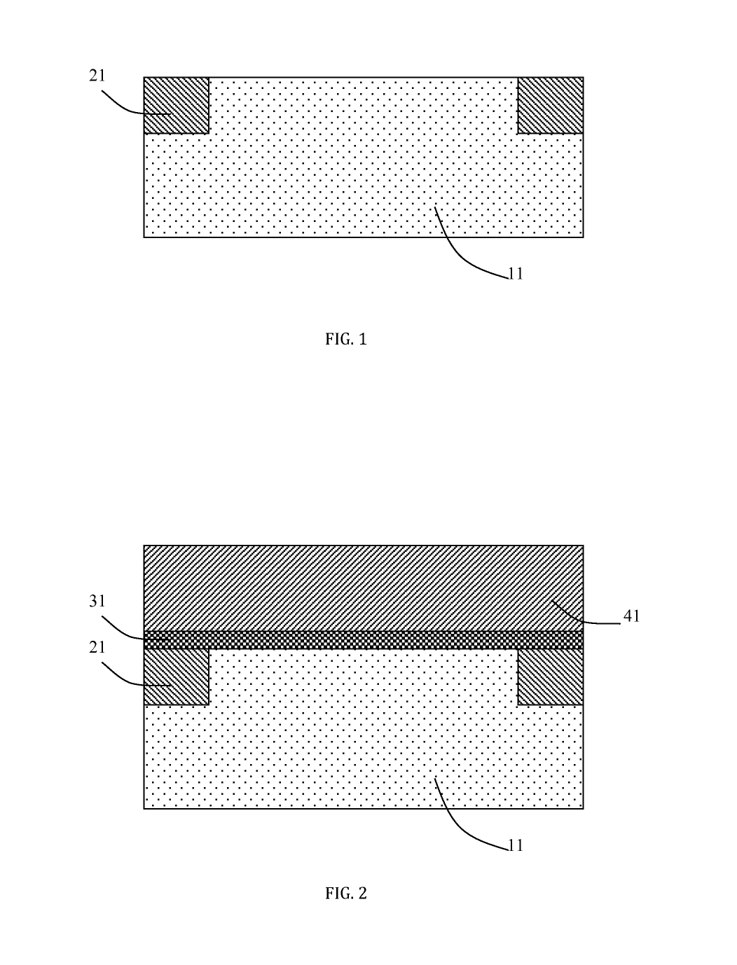

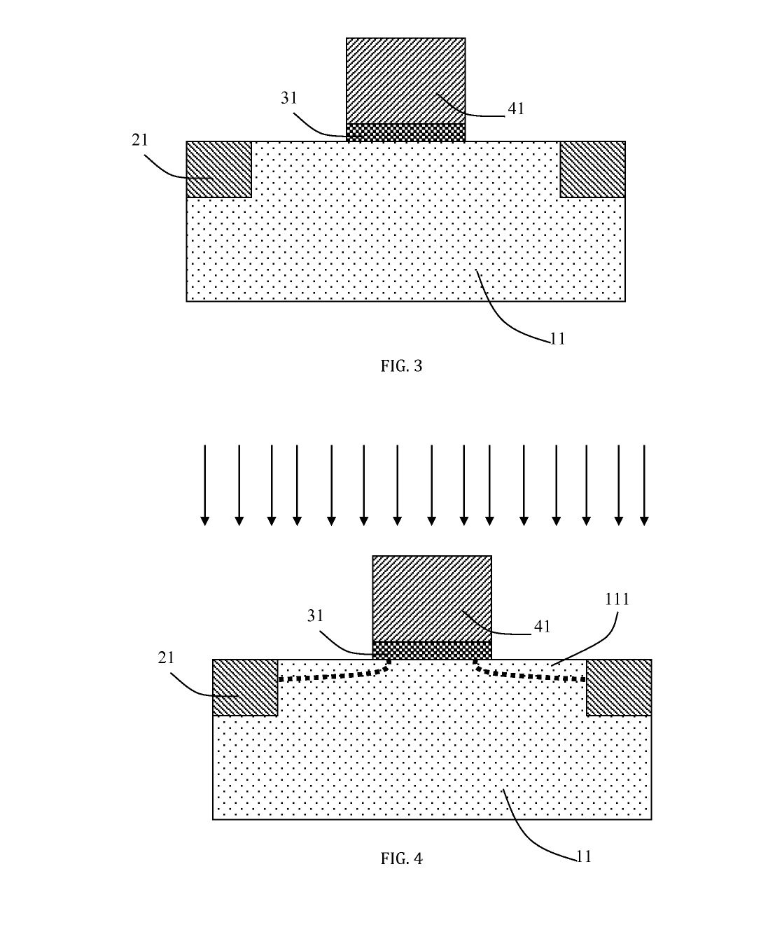

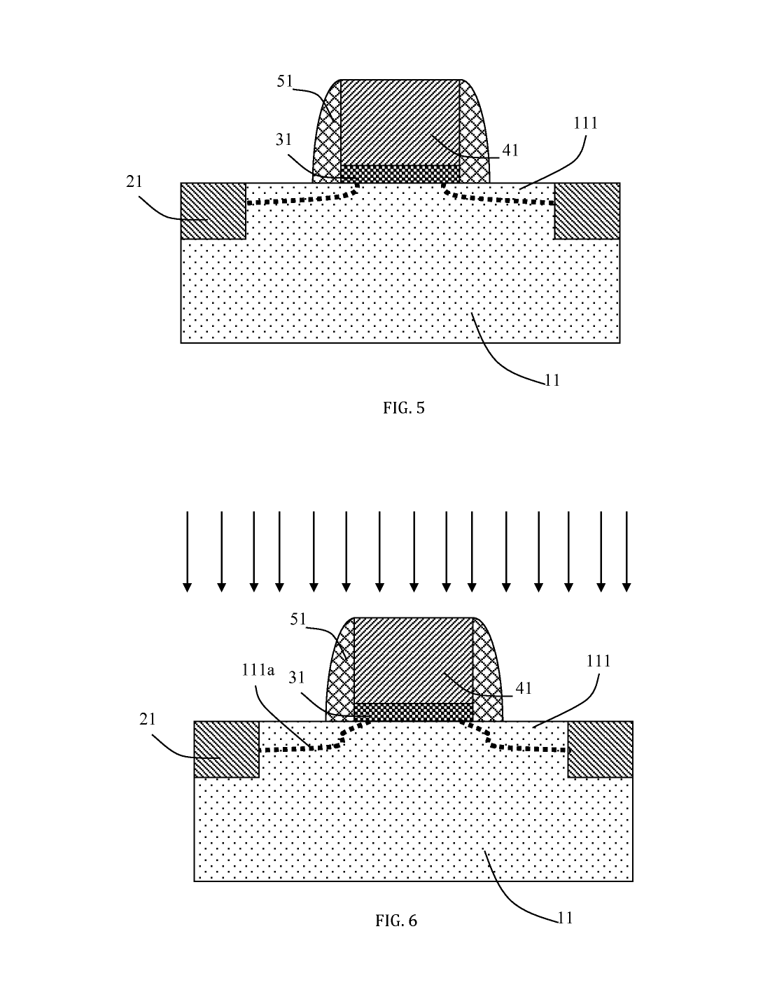

Referring to FIGS. 1-6, using an N-type field-effect transistor as an example, a method according to embodiments of the present invention comprises the following steps:
(1) providing a P-type silicon substrate 11, forming shallow trenches using photolithography and etching processes, and forming shallow trench isolation structures 21 by growing silicon dioxide in the shallow trenches (the p-type silicon substrate 11 can be replaced with silicon-on-insulator);
(2) forming by deposition a high-K dielectric layer 31 and a metal gate electrode layer 41 over the substrate 11 and the shallow trench isolation structures 21, wherein the high-K dielectric layer 31 can be hafnium oxide (HfO₂), hafnium silicon oxide (HfSiO), hafnium silicon oxynitride (HfSiON), silicon oxynitride (SiON), aluminum oxide (Al₂O₃), lanthanum oxide (La₂O₃), zirconium oxide (ZrO₂), a multilayer structure formed by a combination of two of more thereof, or a mixed layer of two or more thereof, and wherein the metal gate electrode layer 41 can be titanium oxide (TiO), tantalum oxide (TaO), metal silicide, tungsten (W), aluminum (Al), ruthenium (Ru), platinum (Pt), a multilayer structure formed by a combination of two of more thereof, a mixed layer of two or more thereof, or a multilayer structure formed by a combination of polysilicon and one or more there of;
(3) forming a gate structure using photolithography and etching processes
(4) implanting N-type dopant ions to form source/drain extension regions 111, wherein the dopants can be phosphorus (N) or arsenic (As), and wherein, before or after this step, P-type dopant ions can be implanted using boron (B), boron fluoride (BF), and/or indium as dopants to form halo regions so as to improve short-channel effect of the device;
(5) depositing an insulating layer, which can be silicon dioxide (SiO₂) or silicon nitride (SiN), and forming sidewalls 51 adhered to sides of the gate electrode;
(6) implanting N-type dopant ions to form source/drain regions of a N-type field-effect transistor and to form P-N junctions 111a between the source/drain regions and the silicon substrate; and
(7) annealing using microwave to activate the implanted ions, wherein annealing temperature does not exceed 400° C., so as to alleviate the effect of annealing on the high-K dielectric, the gate electrode and/or the interface therebetween.

Through the above process steps, a basic metal-oxide-field-effect transistor structure is formed, subsequent processes such as forming metal silicides at the source/drain regions and backend interconnect processes are common processes, and are therefore not discussed in detail here.

In the novel process of making a field-effect transistor provided by the present invention, the high-K dielectric and/or metal gate electrode of the field-effect transistor are formed before the dopants in the source/drain regions are activated. Furthermore, the dopants are activated using microwave annealing techniques, so that the dopants can be activated under relatively low annealing temperature, lessening the effect of source/drain annealing on the high-K dielectric and/or metal gate electrode. Thus, the novel process can become part of the integrated processing technologies for future field-effect transistors.

The above embodiments of the present invention use an N-type field-effect transistors as examples, but can actually be applied to P-type field-effect transistors also. The two types of transistors are different in that opposite types of dopant ions are implanted based on the types of the substrate used. Therefore, the first type and the second type can be defined such that: when the first type is P-type, meaning that the substrate is P-type, N-type dopant ions such as phosphorus (N) or Arsenic (As) are implanted; when the first type is N-type, meaning that the substrate is N-type, P-type dopant ions such as boron (B), boron fluoride (BF₂), and/or indium are implanted.

The above descriptions are preferred embodiments of the present invention. The scope of protection for the present invention is not limited by the above embodiments. Any modification or change of equivalent effect made by those of ordinary skill in the art according to what is disclosed in the present disclosure should all be included in the scope of protection prescribed in the claims.

1. A method of making a field-effect transistor, comprising:
forming shallow trench isolation structures on a substrate of a first type;
depositing a high-K dielectric layer and a metal gate electrode layer over the substrate with the shallow trench isolation structures;
etching the high-K dielectric layer and the metal gate electrode layer to form a gate structure;
implanting dopant ions of a second type into areas of the substrate corresponding to source/drain extension regions;
forming sidewalls on sides of the gate structure;
implanting dopant ions of the second type to into areas of the substrate corresponding to source/drain regions; and
annealing using microwave to activate the implanted ions to form the source/drain extension regions and the source/drain regions, and to form P-N junctions at the interface between the source/drain regions and the silicon substrate.

2. The method of making the field-effect transistor according to claim 1, wherein the substrate of the first type is a silicon substrate or silicon-on-insulator substrate.

3. The method of making the field-effect transistor according to claim 1, wherein the high-K dielectric layer is selected from the group consisting of hafnium oxide, hafnium silicon oxide, hafnium silicon oxynitride, silicon oxynitride, aluminum oxide, lanthanum oxide, zirconium oxide, a multilayer structure formed by a combination of two of more thereof, and a mixed layer of two or more thereof.

4. The method of making the field-effect transistor according to claim 3, wherein the metal gate electrode layer is selected from the group consisting of titanium nitride, tantalum nitride, metal silicide, tungsten, aluminum, ruthenium, platinum, a multilayer structure formed by a combination of two of more thereof, a mixed layer of two or more thereof, and a multilayer structure formed by a combination of polysilicon and one or more thereof

5. The method of making the field-effect transistor according to claim 4, wherein the metal silicide is a compound formed of silicon and one or more metals selected from the group consisting of nickel, titanium, cobalt, and platinum.

6. The method of making the field-effect transistor according to claim 1, wherein the dopants of the second type are N-type dopants when the substrate of the first type is a P-type substrate, and the dopants of the second type are P-type dopants when the substrate of the first type is a N-type substrate.

7. The method of making the field-effect transistor according to claim 1, further comprising: implanting dopant ions of the first type to form halo regions before forming the source/drain extension regions so as to improve device short-channel-effect.

8. The method of making the field-effect transistor according to claim 1, further comprising: implanting dopant ions of the first type to form halo regions after forming the source/drain extension regions so as to improve device short-channel-effect.

9. The method of making the field-effect transistor according to claim 1, wherein the dopants of the first type are boron, boron fluoride or indium when the substrate of the first type is a P-type substrate, and the dopants of the first type are phosphorus or arsenic when the substrate of the first type is a N-type substrate.

10. The method of making the field-effect transistor according to claim 1, wherein temperature during annealing using microwave does not exceed 400° C.

11. A method of making a field-effect transistor, comprising:
forming by deposition a high-K dielectric layer and a metal gate electrode layer over a substrate;
implanting dopant ions for source/drain regions;
performing microwave annealing subsequent to depositing the high-K dielectric layer and the metal gate electrode layer over the substrate, and subsequent to implanting the dopant ions, so as to activate the dopant ions to form the source/drain regions.

12. The method of making the field-effect transistor according to claim 11, wherein the substrate is a silicon substrate or silicon-on-insulator substrate.

13. The method of making the field-effect transistor according to claim 11, wherein the high-K dielectric layer is selected from the group consisting of hafnium oxide, hafnium silicon oxide, hafnium silicon oxynitride, silicon oxynitride, aluminum oxide, lanthanum oxide, zirconium oxide, a multilayer structure formed by a combination of two of more thereof, and a mixed layer of two or more thereof.

14. The method of making the field-effect transistor according to claim 13, wherein the metal gate electrode layer is selected from the group consisting of titanium nitride, tantalum nitride, metal silicide, tungsten, aluminum, ruthenium, platinum, a multilayer structure formed by a combination of two of more thereof, a mixed layer of two or more thereof, and a multilayer structure formed by a combination of polysilicon and one or more thereof.

15. The method of making the field-effect transistor according to claim 14, wherein the metal silicide is a compound formed of silicon and one or more metals selected from the group consisting of nickel, titanium, cobalt, and platinum.

16. The method of making the field-effect transistor according to claim 11, wherein temperature during the microwave annealing does not exceed 400° C.
